(19) United States
(12) Patent Application Publication
(10) Pub. No.: US 2026/0044647 A1
(43) Pub. Date: Feb. 12, 2026

(54) BLANK MODEL GENERATION METHOD, BLANK MODEL ANALYSIS METHOD, AND BLANK MODEL GENERATOR

(71) Applicant: FUTABA INDUSTRIAL CO., LTD., Aichi (JP)

(72) Inventor: Tatsuya YAMADA, Aichi (JP)

(21) Appl. No.: 19/275,224

(22) Filed: Jul. 21, 2025

(30) Foreign Application Priority Data
Aug. 7, 2024 (JP) 2024-130959

(51) Int. Cl. G06F 30/27; G06F 30/17

(52) U.S. Cl. CPC G06F 30/27; G06F 30/17

(57) ABSTRACT

A method for generating a plate-shaped blank model for a simulation is provided. The method includes: acquiring a plurality of sets of three-dimensional coordinates respectively associated with a plurality of positions within a plate-shaped blank material; generating a surface function using a response surface methodology to determine a coordinate of a position within the blank material based on the plurality of sets of three-dimensional coordinates; and generating the blank model using the surface function, the blank model including a point cloud containing a plurality of coordinates.

### CROSS-REFERENCE TO RELATED APPLICATIONS

The present application claims priority based on Japanese Patent Application No. 2024-130959 filed on Aug. 7, 2024 with the Japan Patent Office, the entire disclosure of which is incorporated herein by reference.

### BACKGROUND

The present disclosure relates to a method for generating a plate-shaped blank model for a simulation. The present disclosure also relates to a method for analyzing a blank model and to a blank model generator.

For example, Japanese Patent No. 7409583 discloses a technique for performing a pressing simulation in which a blank model is provided with periodic corrugation, and the simulation is performed with consideration that the blank model includes a curved surface.

### SUMMARY

However, irregularities created in an actual blank material are not limited to periodic corrugation. In cases where the irregularities of a blank material are not corrugations, results of the simulation using a blank model diverges from results of a simulation using the actual blank. Unfortunately, the accuracy of the simulation may be reduced in such cases.

One aspect of the present disclosure is to provide a technique for generating a blank model that allows for improved simulation accuracy.

One aspect of the present disclosure provides a method for generating a plate-shaped blank model for a simulation. The method includes: acquiring a plurality of sets of three-dimensional coordinates respectively associated with a plurality of positions within a plate-shaped blank material; generating a surface function using a response surface methodology to determine a coordinate of a position within the blank material based on the plurality of sets of three-dimensional coordinates; and generating the blank model using the surface function, the blank model including a point cloud containing a plurality of coordinates.

According to this method, the blank model is generated using a response surface methodology; this makes it possible to generate the blank model that matches the properties of the blank material. Thus, this configuration can improve the accuracy of a simulation performed with the blank model.

In one aspect of the present disclosure, the method may further include receiving input of a coordinate in a thickness direction of the blank material in each set of three-dimensional coordinates of the plurality of sets of three-dimensional coordinates. The acquiring a plurality of sets of three-dimensional coordinates may include acquiring the plurality of sets of three-dimensional coordinates, each set of three-dimensional coordinates including the coordinate input in the receiving. For example, the method may further include inputting, performed by an operator, of a coordinate in a thickness direction of the blank material in each set of three-dimensional coordinates of the plurality of sets of three-dimensional coordinates, and the acquiring a plurality of sets of three-dimensional coordinates may include acquiring the plurality of sets of three-dimensional coordinates input by the operator.

This method allows the operator to set coordinates in the direction of the thickness of the blank material as desired, and enables a pressing simulation to be performed using the coordinates.

One aspect of the present disclosure provides a method for analyzing a blank model. The method may include performing a pressing simulation using the blank model, in addition to the elements of the aforementioned method for generating a blank model.

According to this method, the pressing simulation is performed using the blank model that matches the properties of the blank material; this makes it possible to improve the accuracy of the pressing simulation.

In one aspect of the present disclosure, the method may further include generating a plurality of trimmed blanks virtually cut out from the blank model. The performing a pressing simulation may include performing the pressing simulation for each trimmed blank of the plurality of trimmed blanks.

According to this method, the trimmed blanks are cut out from the blank model, and it is thus possible prepare various trimmed blanks depending on the portions of the blank model the trimmed blanks are cut out from. Moreover, the pressing simulation is performed for each of the trimmed blanks. Thus, it is possible to examine the properties of press-formed articles, each made of a different portion of the blank model.

In one aspect of the present disclosure, the method may further include comparing forms of a plurality of press-formed articles subsequent to the pressing simulation.

According to this method, comparing the forms of the plurality of press-formed articles makes it possible to readily identify variations in their properties.

One aspect of the present disclosure may provide a blank model generator configured to generate a plate-shaped blank model for a simulation. The blank model generator includes a coordinate acquirer, a function generator, and a model generator. The coordinate acquirer is configured to acquire a plurality of sets of three-dimensional coordinates respectively associated with a plurality of positions within a plate-shaped blank material. The function generator is configured to generate a surface function using a response surface methodology to determine a coordinate of a position within the blank material based on the plurality of sets of three-dimensional coordinates. The model generator is configured to generate, using the surface function, the blank model that includes a point cloud containing a plurality of coordinates.

With this blank model generator, the blank model is generated using a response surface methodology; this makes it possible to generate the blank model that matches the properties of the blank material. Thus, this blank model generator can improve the accuracy of a simulation performed with the blank model.

### BRIEF DESCRIPTION OF THE DRAWINGS

Some example embodiments of the present disclosure will be described below with reference to the accompanying drawings, in which:

FIG. 1 is a block diagram showing a configuration of a simulator;

FIG. 2 is a flowchart of a simulation process;

FIG. 3 is a plan view showing one example of coordinate measurement points within an actual blank material;

FIG. 4 is a plan view showing one example of trimming;

FIG. 5 is a plan view showing one example of trimmed blanks; and

FIG. 6 is an explanatory diagram showing one example of accuracy comparison results.

### DETAILED DESCRIPTION OF EXEMPLARY EMBODIMENTS

### 1. Embodiment

### [1-1. Configuration]

A simulator 1 of the present embodiment is, for example, a device that generates a blank model and performs a pressing simulation using the blank model generated. The method for generating a blank model of the simulator 1 and its function correspond to a method for generating a blank model and a blank model generator according to the present disclosure. The blank model is a virtual blank material digitally generated.

The blank model generated in the present embodiment is a virtual blank material that is generated by taking account of properties of an actual blank material. The actual blank material is in the form of a substantially flat plate and a material for an article to be shaped by press forming. The description “in the form of a substantially flat plate” means the same as “plate-shaped” according to the present disclosure. The “plate-shaped” refers to a shape having a thickness significantly smaller than its width and length. A plate-shaped actual blank material, for example, means that the actual blank material has a plate shape. In the present embodiment, the pressing simulation is performed using the blank model, without using an actual blank material. It is expected that a virtually press-formed article generated by the pressing simulation has properties similar to those of a press-formed article obtained by pressing an actual blank material. In other words, it is expected that highly accurate results of the pressing simulation are achieved. The method for performing the pressing simulation of the simulator 1 and its function correspond to a method for analyzing a blank model according to the present disclosure.

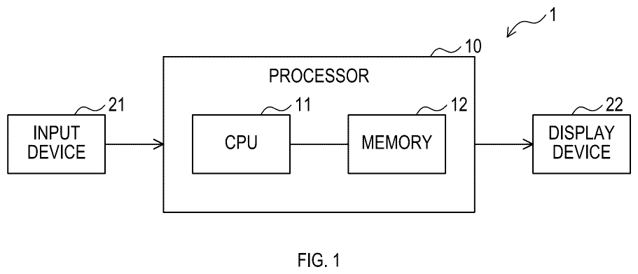

As shown in FIG. 1, the simulator 1 includes a processor 10, an input device 21, and a display device 22.

The input device 21 enables an operator to input an instruction to the simulator 1 and is configured as a keyboard, a mouse, or a touch screen, for example.

The display device 22 displays images for entering instructions, simulation results, and other types of information and is configured as a display or a touch screen, for example.

The processor 10 is equipped with a microcomputer that includes a CPU 11 and a semiconductor memory (hereinafter, referred to as a “memory 12”) such as a RAM or a ROM. Functions of the processor 10 are each implemented by the CPU11 through execution of an associated program stored in a non-transitory tangible recording medium. In this example, the memory 12 corresponds to the non-transitory tangible recording medium storing programs. By executing one of the programs, the method corresponding to the program is executed. The processor 10 may be equipped with a microcomputer or two or more microcomputers.

The manner of implementing one or more functions of each part included in the processor 10 is not limited to software: one or more functions of each part may be implemented using one or more pieces of hardware. For example, in a case where the functions are implemented by electronic circuits, which are hardware, such electronic circuits may be digital, analog, or a combination thereof.

### [1-2. Processing]

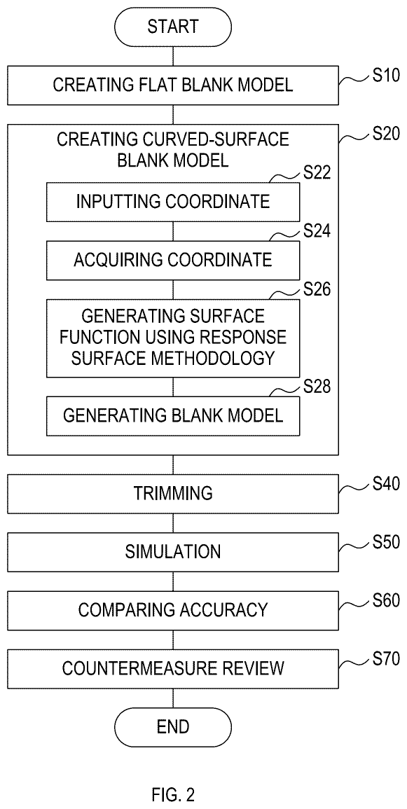

Next, the simulation process executed by the processor 10 will be described with reference to a flowchart in FIG. 2. The simulation process is initiated, for example, in response to the operator's input of an instruction via the input device 21, to perform the pressing simulation.

In the simulation process, first, the processor 10 creates a flat blank model in S10. The flat blank model refers to a plate-shaped blank model that is completely flat and has no irregularities. In the flat blank model, the coordinates in the direction of the thickness (hereinafter also referred to as “thickness direction”) of the blank model are constant (for example, 0) regardless of position. In one example, the coordinates in the thickness direction are, for example, the coordinates at a surface in the thickness direction (specifically, the upper or the lower surface). The coordinates in the thickness direction may be the coordinates at any position, such as the center, in the thickness direction. In a curved-surface blank model which will be described later, the coordinates in the thickness direction are similarly defined.

The flat blank model has, for example, a width of 2000 mm, a depth of 1200 mm, a thickness of 1.0 mm, and a tensile strength of 980 Mpa. The flat blank model may have a plate thickness in the range of, for example, 0.6 mm to 2.0 mm, and an applicable range of tensile strength is, for example, 270 MPa to 1470 MPa. The tensile strength may be less than 270 MPa.

In S20, the processor 10 creates a curved-surface blank model. The processor 10 is set so that the curved-surface blank model will be created having the same size, thickness, and tensile strength as those of the flat blank model. Thus, the curved-surface blank model in the present embodiment is plate-shaped and has, for example, a width of 2000 mm, a depth of 1200 mm, a thickness of 1.0 mm, and a tensile strength of 980 Mpa similarly to the flat blank model.

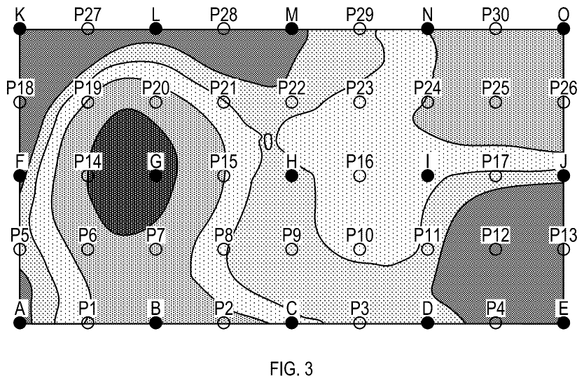

In the process of creating the curved-surface blank model, the processor 10 performs the processes of S22 to S28. Specifically, the processor 10 performs a coordinate input process in S22. In this process, the processor 10 allows the operator to input sets of three-dimensional coordinates at multiple positions within the plate-shaped blank material. In the present embodiment, an actual blank material is used that has irregularities as shown in FIG. 3, for example. In FIG. 3 to FIG. 5, the degree of irregularities of the blank material, the blank model, and the like is represented by color. A portion in a relatively light color has a coordinate value near a reference value (for example, 0) in the thickness direction. A portion in a relatively dark color has a coordinate value that deviates from the reference value in the thickness direction (specifically, the portion has a high degree of irregularities).

The operator selects points on the blank material having such irregularities and, for each point, actually measures the coordinate in the thickness direction of the blank material (for example, coordinates in the thickness direction include coordinates at the position of a surface) and inputs coordinate values of the coordinates of each point as shown in Table 1 below. In other words, the processor 10 receives input of sets of three-dimensional coordinates. The sets of three-dimensional coordinates include the coordinates in the thickness direction of the blank material.

The three-dimensional coordinates fed in the this process are not limited to values obtained by actual measurement and may be corrected measured values, hypothetical values, or other types of values. The feeding of the three-dimensional coordinates is not limited to input of coordinate values by the operator. Data prepared in advance may be acquired as the three-dimensional coordinates; examples of such data include data automatically generated through automated measurement, and data provided by material manufacturers.

TABLE 1

| | x | y | z |
|---|---|---|---|
| A | 0 | 0 | 0 |
| B | 500 | 0 | 3 |
| C | 1000 | 0 | 0 |
| D | 1500 | 0 | −5 |
| E | 2000 | 0 | −10 |
| F | 0 | 600 | 0 |
| G | 500 | 600 | 10 |
| H | 1000 | 600 | 0 |
| I | 1500 | 600 | 0 |
| J | 2000 | 600 | 0 |
| K | 0 | 1200 | −10 |
| L | 500 | 1200 | −5 |
| M | 1000 | 1200 | −5 |
| N | 1500 | 1200 | 3 |
| O | 2000 | 1200 | 5 |

Table 1 is obtained, for example, by the operator measuring the coordinates in the thickness direction (that is, Z-coordinates) of fifteen points, from a point A to a point O, of the blank material, and inputting these values.

In S24, the processor 10 performs a coordinate acquisition. This process is to import the coordinate values of the multiple points that are input by the operator. The coordinate values are imported for calculation. The process of S24 is initiated in response to the operator's input, via the input device 21, indicating that input of the coordinate values has been completed.

In S26, the processor 10 generates a surface function using a response surface methodology. In this process, the processor 10 generates, using a response surface methodology, a surface function with the highest likelihood based on the input coordinate values. The surface function is a function that uniquely determines a Z-coordinate value based on a X-coordinate value and the corresponding Y-coordinate value. As the response surface methodology, Kriging may be used, for example.

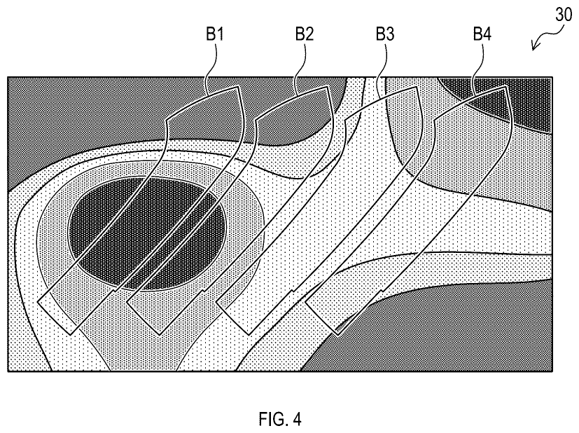

In S28, the processor 10 performs a blank model generation. In this process, an X-coordinate value and the corresponding Y-coordinate value are input into the generated surface function to obtain the corresponding Z-coordinate. This procedure is repeated to obtain point cloud data necessary for a curved-surface blank model. For example, in the example shown in FIG. 3, the coordinate values of a point P1 to a point P30 are obtained in addition to the coordinate values of the point A to the point O that have been already obtained. In other words, it is possible by this process to interpolate coordinates using the surface function obtained by the response surface methodology, and secure the number of coordinates necessary for a curved-surface blank model. In this way, a curved-surface blank model 30 with irregularities is obtained as shown in FIG. 4, for example. In other words, the curved-surface blank model 30 includes a point cloud containing the necessary number of coordinates.

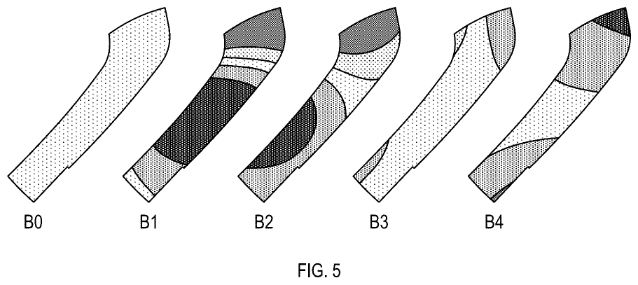

In S40, the processor 10 performs trimming. In this process, the processor 10 virtually cuts out trimmed blanks B1 to B4 of the same shape from the curved-surface blank model 30, for example. In the present embodiment, four trimmed blanks B1 to B4 are generated, for example. One or more trimmed blanks may be generated with respect to each of the trimmed blanks B1 to B4. In this process, the processor 10 also cuts out, from the plane blank model, a trimmed blank B0 having the same shape as the trimmed blanks B1 to B4. As shown in FIG. 5, the trimmed blanks B1 to B4 have irregularities in the direction of their thicknesses and their irregularities differ from each other, whereas the trimmed blank B0 does not have any irregularities in the direction of its thickness.

In S50, the processor 10 performs a simulation. In this process, a pressing simulation is performed in which each of the trimmed blanks B0 to B4 virtually undergoes press forming. The press forming in this step is to obtain press-formed articles of the same shape using virtual dies of the same shape.

In S60, the processor 10 performs an accuracy comparison. In this process, for virtually press-formed articles obtained by the pressing simulation (hereinafter, simply referred to as “press-formed articles”), form accuracy is individually determined based on coordinate differences in respective portions. In other words, whether the press-formed articles which are shaped from the trimmed blanks B0 to B4 have the same form is evaluated by comparing the forms of the press-formed articles. In the present embodiment, the processor 10 aligns the press-formed articles with a specified reference plane and calculates differences in the coordinate values in each press-formed article. The processor 10 generates an image in which portions having differences in the coordinate values are colored in accordance with degrees of the differences. The processor 10 shows the image on the display device 22.

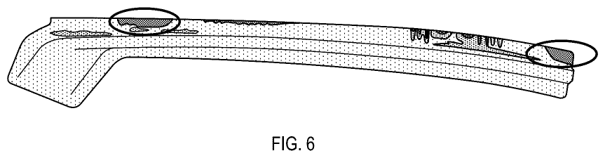

For example, the processor 10 generates an image, as shown in FIG. 6, that facilitates visual recognition of the degrees of the differences determined by comparing the coordinate values of the press-formed articles, and shows this image on the display device 22. In the example shown in FIG. 6, darker colors indicate greater differences in the coordinate values of the press-formed articles. From this image, it is understood, for example, that the areas enclosed by ovals in FIG. 6 have greater differences in the coordinate values and low accuracy.

In determining the differences in the coordinate values of the press-formed articles, the average of errors in the coordinate values of the respective press-formed articles made of the trimmed blanks B0 to B4 may be used, or the maximum values, for example, of the errors may be used. Alternatively, the coordinate values of the trimmed blank B0 may be used as reference coordinate values, and the differences in the coordinate values of the trimmed blanks B1 to B4 relative to the reference coordinate values may be used. In this case, the difference between the averages of the coordinate values of the trimmed blanks B1 to B4 and the coordinate values of the trimmed blank B0 may be used as the errors. Alternatively, the differences between the maximum values of the coordinate values of the trimmed blanks B1 to B4 and the coordinate values of the trimmed blank B0 may be used as the errors.

In S70, the processor 10 performs a process that allows the operator to input results of a countermeasure review via the input device 21. In this process, the operator can input, for example, a revision to the processing method and/or a revision to the form (for example, adding a bead or other reinforcement portions). Thus, the processor 10 can apply the results of the input to the settings for the simulation process to be performed next time. Upon completion of this process, the simulation process is terminated.

### [1-3. Effects]

According to the embodiment described above, the following effects are achieved.

(1a) The simulator 1 performs the method for generating a plate-shaped blank model for a simulation. The method includes: acquiring a plurality of sets of three-dimensional coordinates respectively associated with a plurality of positions within a plate-shaped blank material; generating a surface function using a response surface methodology to determine a coordinate of a position within the blank material based on the plurality of sets of three-dimensional coordinates; and generating, using the surface function, the blank model 30 that includes a point cloud containing a plurality of coordinates.

According to this configuration, the blank model 30 is generated using the response surface methodology; this makes it possible to generate the blank model 30 that matches the properties of the blank material. Thus, this configuration can improve the accuracy of a simulation performed with the blank model 30.

(1b) The simulator 1 further performs the pressing simulation using the blank model 30.

According to this configuration, the pressing simulation is performed using the blank model 30 that matches the properties of the blank material. Thus, this configuration allows for improved accuracy of the pressing simulation.

(1c) The simulator 1 receives the operator's input of a coordinate in the direction of the thickness of the blank material in each set of the three-dimensional coordinates and acquires the plurality of sets of three-dimensional coordinates input by the operator.

This configuration allows the operator to set coordinates in the direction of the thickness axis of the blank material as desired, and enables the pressing simulation to be performed using the coordinates.

(1d) The simulator 1 generates the trimmed blanks B1 to B4 that are virtually cut out from the blank model 30. In the pressing simulation, the simulator 1 performs the pressing simulation for each of the trimmed blanks B1 to B4.

According to this configuration, the trimmed blanks B1 to B4 are cut out from the blank model 30; this makes it possible to prepare various trimmed blanks depending on the portions of the blank model 30 the trimmed blanks B1 to B4 are cut out from. Moreover, the pressing simulation is performed for each of the trimmed blanks B1 to B4. Thus, it is possible to examine the properties of press-formed articles, each made of a different portion of the blank model 30.

(1e) The simulator 1 compares the forms of the press-formed articles.

According to this configuration, comparing the forms of the press-formed articles makes it possible to readily identify variations in their properties.

(1f) The simulator 1 aligns the press-formed articles with a specified reference plane and shows the aligned press-formed articles on the display device 22.

According to this method, the press-formed articles are superimposed on each other by aligning the press-formed articles with a reference plane. This enables the differences in deformation amounts for each of the trimmed blanks B1 to B4 to be calculated as coordinate value differences, and facilitates visual recognition of the coordinate value differences by means of color coding in accordance with degrees of the differences.

### 2. Other Embodiments

An embodiment of the present disclosure has been described above. However, the present disclosure should not be limited to the above-described embodiment and may be carried out in various forms.

(2a) The above embodiment illustrates a configuration in which the simulator 1 performs a pressing simulation. However, the simulation performed by the simulator 1 is not limited to the pressing simulation. The simulator 1 may perform a simulation, such as a tensile test, a fatigue test, and a buckling test.

(2b) The processor 10 and the procedure performed by the processor 10 described in the present disclosure may be achieved by a dedicated computer provided with a processor and a memory programmed to perform one or more functions implemented by a computer program. Alternatively, the processor 10 and the procedure performed by the processor 10 described in the present disclosure may be achieved by a dedicated computer configured with one or more dedicated hardware logic circuits. Alternatively, the processor 10 and the procedure performed by the processor 10 described in the present disclosure may be achieved by one or more dedicated computers including a combination of a processor and a memory programmed to perform one or more functions, and a processor configured with one or more dedicated hardware logic circuits. The computer program may be stored in a computer-readable non-transitory recording medium as instructions to be executed by the computer. Software is not necessarily included in the manner of implementing a function of each part included in the processor 10; all of the functions may be achieved by using one or more pieces of hardware.

(2c) Functions of one element in the aforementioned embodiments may be distributed to two or more elements, or functions of two or more elements may be achieved by one element. A part of the configurations of each of the aforementioned embodiments may be omitted. In addition, at least a part of the configurations of each of the aforementioned embodiments may be added to or replaced with another part the configurations of the aforementioned embodiments.

(2d) Other than the aforementioned simulator 1, the present disclosure can be achieved in various forms, such as in the forms of: a system comprising the simulator 1 as an element; a program for causing a computer to function as the simulator 1; a non-transitory tangible storage medium such as a semiconductor memory storing this program; a blank model generation method; and a simulation method.

What is claimed is:

1. A method for generating a plate-shaped blank model for a simulation, the method comprising:
acquiring a plurality of sets of three-dimensional coordinates respectively associated with a plurality of positions within a plate-shaped blank material;
generating a surface function using a response surface methodology to determine a coordinate of a position within the blank material based on the plurality of sets of three-dimensional coordinates; and
generating the blank model using the surface function, the blank model including a point cloud containing a plurality of coordinates.

2. The method according to claim 1, further comprising
receiving input of a coordinate in a thickness direction of the blank material in each set of three-dimensional coordinates of the plurality of sets of three-dimensional coordinates,
wherein the acquiring a plurality of sets of three-dimensional coordinates includes acquiring the plurality of sets of three-dimensional coordinates, each set of three-dimensional coordinates including the coordinate input in the receiving.

3. A method for analyzing a blank model by a simulation, the method comprising:
acquiring a plurality of sets of three-dimensional coordinates respectively associated with a plurality of positions within a plate-shaped blank material;
generating a surface function using a response surface methodology to determine a coordinate of a position within the blank material based on the plurality of sets of three-dimensional coordinates;
generating the blank model using the surface function, the blank model including a point cloud containing a plurality of coordinates; and
performing a pressing simulation using the blank model.

4. The method according to claim 3, further comprising
generating a plurality of trimmed blanks virtually cut out from the blank model,
wherein the performing a pressing simulation includes performing the pressing simulation for each trimmed blank of the plurality of trimmed blanks.

5. The method according to claim 4, further comprising
comparing forms of a plurality of press-formed articles obtained by the pressing simulation.

6. A blank model generator configured to generate a plate-shaped blank model for a simulation, the blank model generator comprising:
a coordinate acquirer configured to acquire a plurality of sets of three-dimensional coordinates respectively associated with a plurality of positions within a plate-shaped blank material;
a function generator configured to generate a surface function using a response surface methodology to determine a coordinate of a position within the blank material based on the plurality of sets of three-dimensional coordinates; and
a model generator configured to generate, using the surface function, the blank model that includes a point cloud containing a plurality of coordinates.
